(19) United States
(12) Patent Application Publication
(10) Pub. No.: US 2010/0124101 A1
(43) Pub. Date: May 20, 2010

(54) PHASE-CHANGE RANDOM ACCESS MEMORY DEVICE

(75) Inventors: Mu-hui Park, Seoul (KR); Soo-guil Yang, Yongin-si (KR); Kwang-ho Kim, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/499,894

(22) Filed: Jul. 9, 2009

(30) Foreign Application Priority Data
Nov. 14, 2008 (KR) 1020080113343

(51) Int. Cl. G11C 11/00; G11C 7/00

(52) U.S. Cl. 365/163; 365/203; 365/148

(57) ABSTRACT

Provided is a phase-change random access memory device. The phase-change random access memory device includes a phase-change memory cell array having multiple phase-change memory cells, a sensing unit and a discharge unit. The sensing unit detects data, stored in a phase-change memory cell to be sensed of the multiple phase-change memory cells, during a sensing period. The discharge unit discharges at least one node of multiple nodes positioned on a sensing path between the phase-change memory cell array and the sensing unit during a period other than the sensing period.

### PRIORITY CLAIM

A claim of priority is made to Korean Patent Application No. 10-2008-0113343, filed on Nov. 14, 2008, in the Korean Intellectual Properly Office, the subject matter of which is hereby incorporated by reference.

### SUMMARY

Embodiments of the present inventive concept relate to a phase-change random access memory device, and more particularly, to a phase-change random access memory device which discharges nodes positioned on a sensing path during periods other than a sensing period.

Phase-change random access memory (PRAM) is non-volatile memory that stores data using material, such as germanium, antimony and tellurium (GeSbTe), called “GST,” the resistivity of which changes according to phase-changes corresponding to temperature changes (hereinafter, referred to as phase-change material). Generally, PRAM has non-volatile and low power consumption characteristics, together with the characteristics of dynamic random access memory (DRAM). Thus, PRAM has been recognized as next-generation memory.

According to an aspect of the present invention, there is provided a phase-change random access memory device, including a phase-change memory cell array, a sensing unit and a discharge unit. The phase-change memory cell array includes multiple phase-change memory cells. The sensing unit detects data, stored in a phase-change memory cell to be sensed of the multiple phase-change memory cells, during a sensing period. The discharge unit discharges at least one node positioned on a sensing path between the phase-change memory cell array and the sensing unit during a period other than the sensing period.

The discharge unit may discharge the at least one node positioned on the sensing path with a ground voltage.

The discharge unit may include a first terminal connected to the at least one node, a second terminal connected to the ground voltage, and at least one discharge transistor including a gate that receives a discharge control signal. The discharge control signal may be disabled during the sensing period and enabled during the period other than the sensing period.

The phase-change memory cell to be sensed is connected to a word line and a bit line. The sensing unit may compare a voltage of the bit line connected to the phase-change memory cell to be sensed with a reference voltage to detect the data stored in the phase-change memory cell to be sensed.

### BRIEF DESCRIPTION OF THE DRAWINGS

The embodiments of the present invention will be described with reference to the attached drawings, in which:

FIG. 1 is a block diagram of a phase-change random access memory device, according to an embodiment of the invention;

FIG. 2 is a circuit diagram of a phase-change random access memory device, according to an embodiment of the invention;

FIG. 3 is a timing diagram illustrating an operation of the phase-change random access memory device illustrated in FIG. 2;

FIG. 4 is a block diagram showing a discharge control signal generating unit of the phase-change random access memory device illustrated in FIG. 2, according to an embodiment of the invention;

FIG. 5 is a circuit diagram of a representative diode type phase-change memory cell of the phase-change memory cell array illustrated in FIGS. 1 and 2, according to an embodiment of the invention;

FIG. 6 is a cross-sectional view of a memory device including the phase-change material illustrated in FIG. 5; and

FIG. 7 is a graph showing characteristics of the phase-change material illustrated in FIGS. 5 and 6, according to an embodiment of the invention.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

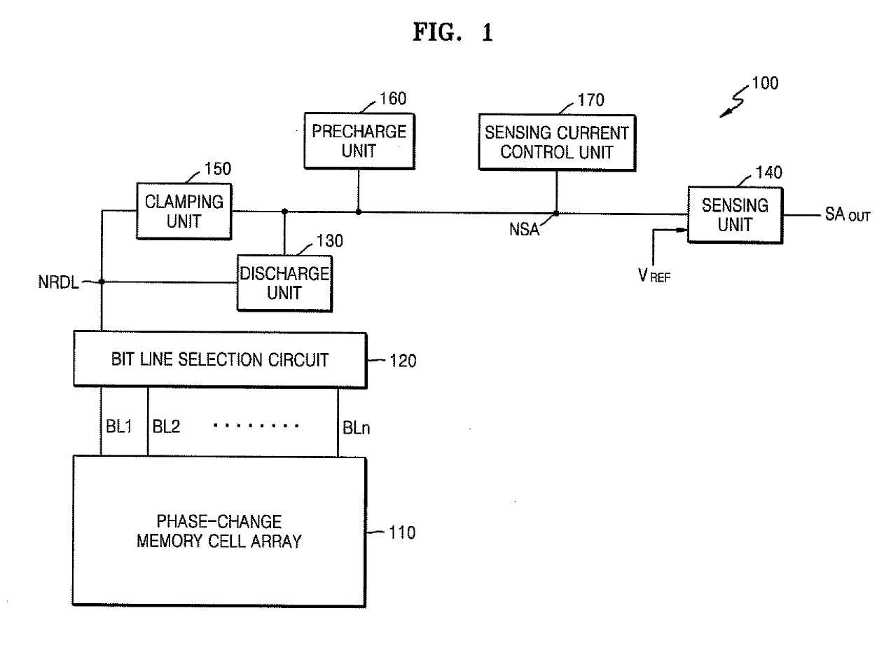

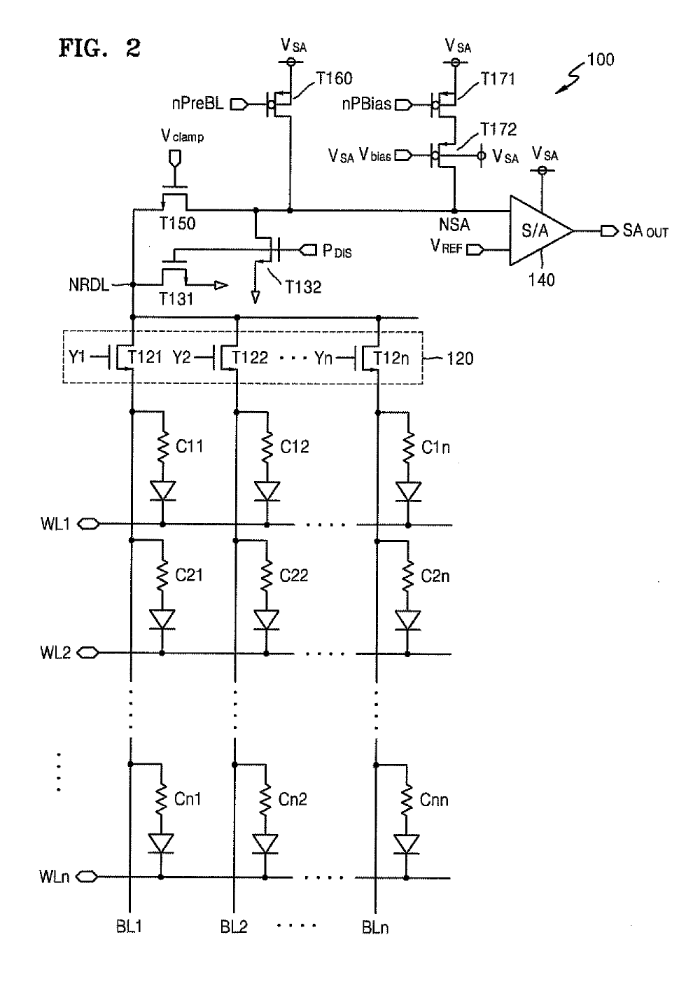

FIG. 1 is a block diagram of a phase-change random access memory device, according to an illustrative embodiment of the present invention. FIG. 2 is a circuit diagram of a phase-change random access memory device, according to another illustrative embodiment of the present invention.

Referring to FIGS. 1 and 2, the phase-change random access memory device 100 includes a phase-change memory cell array 110, a bit line selection circuit 120, a discharge unit 130, and a sensing unit 140.

The phase-change memory cell array 110 includes multiple phase-change memory cells C11 through Cnn arranged in an array. The sensing unit 140 detects data stored in a phase-change memory cell to be sensed, among the phase-change memory cells C11 through Cnn.

The discharge unit 130 discharges one or more sensing nodes, depicted by representative sensing nodes NRDL and NSA, positioned on a sensing path formed between the phase-change memory cell array 110 and the sensing unit 140. The discharge unit 130 discharges the nodes NRDL and NSA in periods other than a sensing period, during which the sensing unit 140 detects data stored in the phase-change memory cell to be sensed of the phase-change memory cell array 110. For example, the discharge unit 130 may discharge the nodes NRDL and NSA to a ground voltage before and after the sensing period.

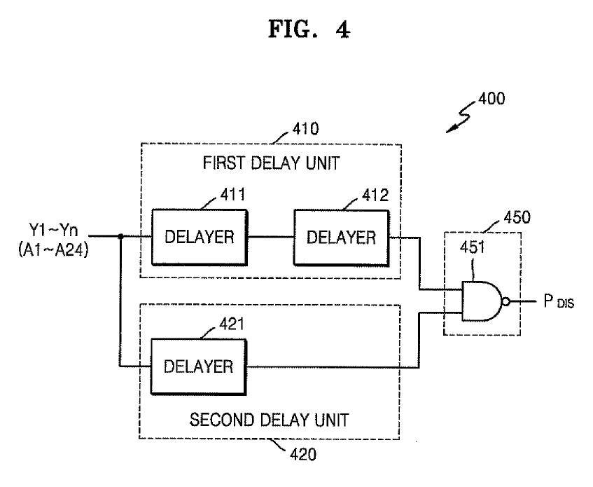

The discharge unit 130 may include discharge transistors T131 and T132. A first terminal (drain or source) of the discharge transistor T131 is connected to the node NRDL, and a second terminal (source or drain) of the discharge transistor T131 is connected to the ground voltage. A first terminal (drain or source) of the discharge transistor T132 is connected to the node NSA, and a second terminal (source or drain) of the discharge transistor T132 is connected to the ground voltage. In addition, gates of the discharge transistors T131 and T132 receive a discharge control signal P_{DIs}. The discharge control signal P_{DIS} is disabled during the sensing period and enabled during any period other than the sensing period. Accordingly, the discharge transistors T131 and T132 are turned on during the periods other than the sensing period, thus connecting the nodes NRDL and NSA to the ground voltage to be discharged to the ground voltage. The discharge transistors T131 and T132 are turned off during the sensing period, thus disconnecting the nodes NRDL and NSA from the ground voltage to prevent discharging to the ground voltage. An example of a discharge control signal generating unit that generates control signal P_{DIS} will be described below with reference to FIG. 4.

The bit line selection circuit 120 may include bit line selection units T121, T122, . . . , and T12n. The bit line selection units T121, T122, . . . , and T12n are respectively connected between bit lines BL1, BL2, . . . , and BLn and the nodes NRDL and NSA. The bit line selection units T121, T122, . . . , and T12n select bit lines connected to a memory cell to be sensed. For purposes of explanation, it may be assumed that representative phase-change memory cell Cln, for example, is a memory cell to be sensed. Accordingly, the bit line selection unit T12n is turned on in response to a bit line selection control signal Yn, connecting the memory cell to be sensed Cln and the bit line BLn to the nodes NRDL and NSA and the sensing unit 140. The other bit line selection units T121, T122, etc., operate in a similar manner to the bit line selection unit T12n in response to bit line selection control signals Y1, Y2, etc., respectively.

The sensing unit 140 detects data stored in the phase-change memory cell to be sensed Cln by comparing a voltage of the bit line, BLn, connected to the phase-change memory cell to be sensed Cln, with a reference voltage V_{REF}.

The phase-change random access memory device 100 according to the current embodiment may further include a sensing current control unit 170 and a precharge unit 160 and/or a clamping unit 150.

The sensing current control unit 170 allows a sensing current to flow through the sensing path and adjusts the amount of sensing current. The sensing current is supplied to the phase-change memory cell to be sensed Cln and is used to detect data stored in the phase-change memory cell to be sensed. The sensing current control unit 170 may include two transistors T171 and T172, for example, which are connected in series. The transistor T171 supplies a sensing current to at least the node NSA in response to a sensing current control signal nPBias. The sensing current supplied to the node NSA may be supplied to the phase-change memory cells C11 through Cnn via the sensing path. The transistor T172 determines the amount of the sensing current supplied to the node NSA in response to a sensing current amount control signal V_{bias}. The amount of the sensing current supplied to the node NSA may be changed according to a voltage level of the sensing current amount control signal V_{bias}. The sensing current control unit 170 may also supply the sensing current to the node NRDL, for example, through the clamping unit 150.

The precharge unit 160 precharges at least the node NSA positioned on the sensing path formed between the phase-change memory cells C11 through Cnn and the sensing unit 140. The precharge unit 160 may include a precharge transistor TI60. The transistor T160 precharges the node NSA in response to a precharge control signal nPreBL during at least a portion of the sensing period. For example, the precharge transistor T160 may precharge the node NSA with a V_{SA} voltage level. The precharge unit 160 may also precharge the node NRDL, for example, through the clamping unit 150.

The clamping unit 150 is connected between the sensing unit 140 and the phase-change memory cells C11 through Cnn of the phase-change memory cell array 110. The clamping unit 150 is configured to selectively connect the sensing unit 140 to one or more phase-change memory cells C11 through Cnn of the phase-change memory cell array 110 via the bit line selection circuit 120, or to disconnect the sensing unit 140 from the phase-change memory cells C11 through Cnn via the bit line selection circuit 120. More particularly, the clamping unit 150 may include a clamping transistor T150, which is turned on or off in response to a clamping control signal V_{clamp}. When the clamping transistor T150 is turned on, the sensing unit 140 and selected phase-change memory cells of the phase-change memory cell array 110 may be connected to one another. When the clamping transistor T150 is turned off, the sensing unit 140 and the phase-change memory cells of the phase-change memory cell array 110 may not connected to one another.

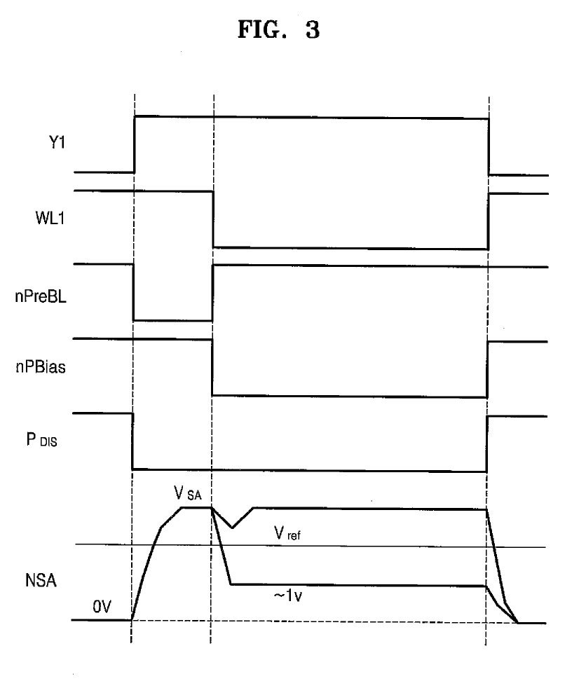

FIG. 3 is a timing diagram illustrating an operation of the phase-change random access memory device illustrated in FIG. 2, which depicts an example in which the phase-change memory cell to be sensed is C11.

Referring to FIG. 3, a sensing operation is not performed during a disable period, in which the representative bit line selection control signal Y1 has a logic low level. During the disable period, the discharge control signal P_{DIS} is maintained at a logic high level (an enable state). Accordingly, referring to FIG. 2, the discharge transistors T131 and T132 in are turned on and the nodes NRDL and NSA are discharged. For example, the nodes NRDL and/or NSA may be discharged with a ground voltage level.

When the bit line selection control signal Y1 transitions to a logic high level (enabled), the sensing operation starts. The bit line selection transistor T121 corresponding to bit line BL1 is turned on. When the bit line selection control signal Y1 transitions to the logic high level, the discharge control signal P_{DIS} transitions to a logic low level. Accordingly, the discharge transistors T131 and T132 are turned off and do not discharge the nodes NRDL and NSA. Also, when the bit line selection control signal Y1 transitions to the logic high level, the precharge control signal nPreBL transitions to a logic low level. Accordingly, the precharge transistor T160 is turned on and precharges the nodes NRDL and NSA. For example, the nodes NRDL and NSA may be precharged with the V_{SA} voltage level.

Next, when word line control signal WL1 transitions to a logic low level, the corresponding word line WL1 is enabled, where the word line control signal and the word line have the same reference numeral. When word line WL1 is enabled, the phase-change memory cell to be sensed C11, connected to the selected bit line BL1, is selected.

In addition, when the sensing current control signal nPBias transitions to a logic low level, a sensing current is supplied to the phase-change memory cell to be sensed C11, and a sensing operation is performed, as previously described. Voltage levels of the bit line BL1 and the node NSA change depending on whether data stored in the phase-change memory cell to be sensed C11 is “1” or “0”. FIG. 3 illustrates both the case in which the voltage level of the node NSA is higher than reference voltage V_{REF} and the case in which the voltage level of the node NSA is lower than the reference voltage V_{REF}. An operation of detecting data stored in the phase-change memory cell to be sensed C11 by comparing the voltage level of the node NSA and the reference voltage V_{REF}, where the operation is performed by the sensing unit 140, has been previously described.

FIG. 4 is a block diagram showing a discharge control signal generating unit 400 of the phase-change random access memory device illustrated in FIG. 2, according to an illustrative embodiment of the present invention.

Referring to FIG. 4, the discharge control signal generating unit 400 generates the discharge control signal P_{DIS} used to control the discharge transistors T131 and T132. The discharge control signal P_{DIS} is disabled during a sensing period and enabled in periods other than the sensing period.

in the depicted embodiment, the discharge control signal generating unit 400 includes a first delay unit 410, a second delay unit 420, and a logic operation unit 450.

The first delay unit 410 delays column addresses Y1 through Yn (e.g., A1 through A24) for a first delay time, and the second delay unit 420 delays the column addresses Y1 through Yn (e.g., A1 through A24) for a second delay time that is shorter than the first delay time. For example, the first delay unit 410 may include two delayers 411 and 412 connected in series, and the second delay unit 420 may include one delayer 421, so that the second delay time is shorter than the first delay time. Of course, in various embodiments, the number of delayers of the first delay unit 410 and the number of delayers of the second delay unit 420 may vary, without departing from the scope of the present teachings, under the condition that the number of delayers of the first delay unit 410 is larger than the number of delayers of the second delay unit 420.

The logic operation unit 450 performs a logic operation on an output of the first delay unit 410 and an output of the second delay unit 420, and generates the discharge control signal P_{DIS}. For example, the logic operation unit 450 may be a NAND logic gate.

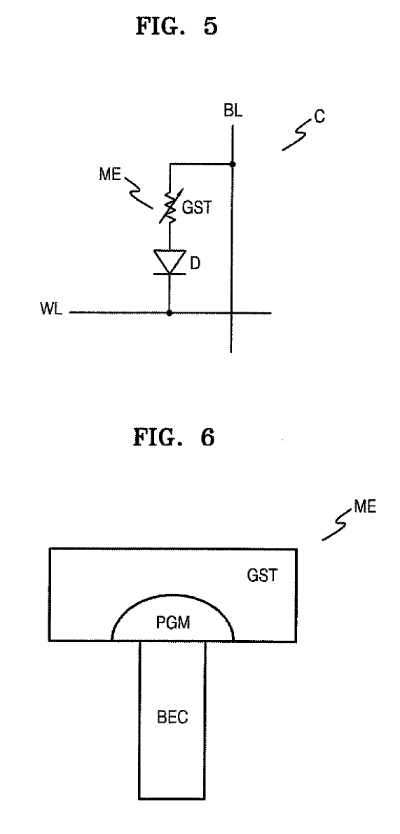

FIG. 5 is an equivalent circuit diagram of a diode type phase-change memory cell that can be included in the phase-change memory cell array illustrated in FIGS. 1 and 2, according to an illustrative embodiment of the present invention.

A diode type phase-change memory cell C is illustrated in FIG. 5. The phase-change memory cell array of FIGS. 1 and 2 may include multiple diode type phase-change memory cells C, as illustrated in FIG. 5.

Each of the diode type phase-change memory cells C includes a memory device ME and a P-N diode D. The memory device ME include a phase-change material, such as GST (germanium, antimony and tellurium (GeSbTe)), connected to a bit line BL. More particularly, the phase-change material GST is connected to a P-junction of the diode D, and a word line WL is connected to an N-junction of the diode D.

The phase-change material GST of the memory device ME becomes amorphous or crystallized, according to temperature and heating time, so that data can be stored in the diode type phase-change memory cell C. For phase-change of the phase-change material GST, high temperature (e.g., over 900° C.) is needed. The high temperature is obtained due to Joule heating using a current that flows through the diode type phase-change memory cell C.

FIG. 6 is a cross-sectional view of a memory device, including a phase-change material illustrated in FIG. 5. Referring to FIG. 6, PGM is a portion of the phase-change material GST which contacts a lower electrode BEC of the memory device ME. When the current is supplied to the lower electrode BEC, the volume and state of PGM are changed. The crystalline state of the phase-change material GST is determined due to the changes of PGM.

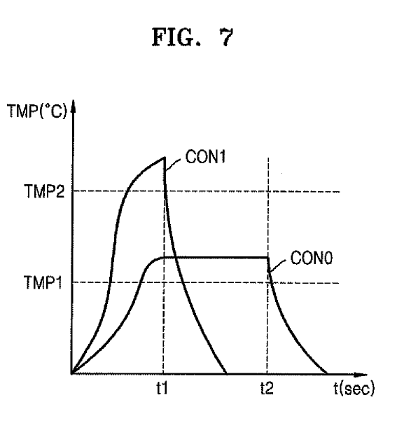

FIG. 7 is a graph showing representative characteristics of the phase-change material shown in FIGS. 5 and 6. In this regard, reference numeral CON1 denotes a condition in which the phase-change material GST becomes amorphous, and reference numeral CON0 denotes a condition in which the phase-change material GST becomes crystallized. A write operation and a read operation of the phase-change random access memory device will be described with reference to FIGS. 5 through 7.

With respect to the write operation, in order to store data “1”, the phase-change material GST is heated to over a melting temperature TMP2 at time t1, and then rapidly cooled, so that the phase-change material GST becomes amorphous. The amorphous state is defined as data “1” and is referred to as a “reset state.” In order to store data “0”, the phase-change material GST is heated to over a crystallization temperature TMP1 and is maintained for a predetermined amount of time t2, and then the phase-change material is slowly cooled. In this case, the phase-change material becomes crystallized. This state is defined as data “0” and is referred to as a “set state.”

With respect to the read operation, the memory cell is selected to be read by selecting bit line BL and word line WL, which correspond to each other. A read current is supplied to the selected memory cell C so that “1” and “0” can be differentiated by using a difference in voltage change due to the resistivity state of the phase-change material GST.

It is understood that the phase-change memory cells shown in FIGS. 1 and 2 are for purposes of explanation, and that other types of resistive change memory cells may be included in various embodiments without departing from the scope of the present teachings. For example, resistive change memory cells, such as magnetoresistive random access memory (MRAM), resistive random access memory (ReRAM) or RaceTrack memory, may be included.

While the present inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A phase-change random access memory device, comprising:
a phase-change memory cell array comprising a plurality of phase-change memory cells;
a sensing unit detecting data stored in a phase-change memory cell to be sensed of the plurality of phase-change memory cells, during a sensing period; and
a discharge unit discharging at least one node positioned on a sensing path between the phase-change memory cell array and the sensing unit during a period other than the sensing period.

2. The device of claim 1, wherein the discharge unit discharges the at least one node positioned on the sensing path with a ground voltage.

3. The device of claim 2, wherein the discharge unit comprises:
a first terminal connected to the at least one node;
a second terminal connected to the ground voltage; and
at least one discharge transistor comprising a gate receiving a discharge control signal,
wherein the discharge control signal is disabled during the sensing period and enabled during the period other than the sensing period.

4. The device of claim 1, further comprising:
a discharge control signal generating unit generating a discharge control signal that is disabled during the sensing period and enabled during the period other than the sensing period,
wherein the discharge control signal generating unit comprises:
a first delay unit delaying a column address for a first delay time;
a second delay unit delaying the column address for a second delay time that is shorter than the first delay time; and
a logic operation unit performing a logic operation on an output of the first delay unit and an output of the second delay unit.

5. The device of claim 1, further comprising:
a plurality of word lines and a plurality of bit lines, wherein the plurality of phase-change memory cells are connected to the word lines and the bit lines, respectively, and wherein the sensing unit detects a voltage of a bit line connected to the phase-change memory cell to be sensed to detect the data stored in the phase-change memory cell to be sensed.

6. The device of claim 5, wherein the sensing unit compares the voltage of the bit line connected to the phase-change memory cell to be sensed with a reference voltage to detect the data stored in the phase-change memory cell to be sensed.

7. The device of claim 5, further comprising:
a plurality of bit line selection units connected between the plurality of bit lines and the sensing path.

8. The device of claim 7, wherein the at least one node discharged by the discharge unit comprises an NRDL node positioned between the bit line selection units and a clamping unit.

9. The device of claim 1, further comprising:
a sensing current control unit allowing a sensing current to flow through the sensing path and adjusting an amount of the sensing current; and
a precharge unit precharging the at least one node positioned on the sensing path between the phase-change memory cell array and the sensing unit.

10. The device of claim 9, wherein the at least one node discharged by the discharge unit comprises an NSA node positioned between the sensing current control unit and the discharge unit.

11. The device of claim 9, wherein the at least one node discharged by the discharge unit comprises an NSA node positioned between the precharge unit and the discharge unit.

12. The device of claim 1, further comprising:
a clamping unit connected between the sensing unit and the phase-change memory cell array, wherein the at least one node discharged by the discharge unit comprises a first node positioned between the sensing unit and the clamping unit and a second node positioned between the clamping unit and the phase-change memory cell array.

13. The device of claim 1, wherein the phase-change memory cell array comprises a plurality of diode type phase-change memory cells.

14. A phase-change random access memory device, comprising:
a phase-change memory cell array comprising a plurality of phase-change memory cells;
a sensing unit configured to detect data, stored in a phase-change memory cell to be sensed of the plurality of phase-change memory cells, during a sensing period;
a sensing node connected between the sensing unit and the phase-change memory cell array on a sensing path;
a sensing current control unit connected to the sending node and configured to adjust a sensing current flowing through the sensing path;
a precharge unit connected to the sending node and configured to precharge the sensing node during a portion of the sensing period; and
a discharge unit connected to the sending node and configured to discharge the sensing node during a period other than the sensing period.
